(19) United States
(12) Patent Application Publication
(10) Pub. No.: US 2021/0406507 A1
(43) Pub. Date: Dec. 30, 2021

(54) UNDER-SCREEN FINGERPRINT IDENTIFICATION DEVICE, DISPLAY PANEL, AND DISPLAY DEVICE

(71) Applicant: Wuhan China Star Optoelectronics Technology Co., Ltd., Wuhan (CN)

(72) Inventor: Chuan SHUAI, Wuhan (CN)

(73) Assignee: Wuhan China Star Optoelectronics Technology Co., Ltd., Wuhan (CN)

(21) Appl. No.: 16/771,758

(22) PCT Filed: Nov. 11, 2019
(86) PCT No.: PCT/CN2019/117091

§ 371 Date: Jun. 11, 2020

(30) Foreign Application Priority Data
Oct. 28, 2019 (CN) 201911028326.4

(51) Int. Cl. G06K 9/00; G06F 3/042

(52) U.S. Cl. CPC G06K 9/0004; G02B 5/20; G06F 3/042

(57) ABSTRACT

The present disclosure provides an under-screen fingerprint identification device, a display panel, and a display device. In the present disclosure, light control films are added to pixel opening areas to distinguish fingerprint identification light from normal display light, and image sensors are set to only identify invisible light, so invisible light can be transmitted to the image sensors only through pinholes in a pinhole layer, thereby improving a signal-to-noise ratio of a fingerprint identification signal.

### FIELD OF INVENTION

The present disclosure relates to the field of fingerprint identification technology, and particularly relates to an under-screen fingerprint identification device, a display panel, and a display device.

### BACKGROUND OF INVENTION

With development of electronic technology, display screens of electronic equipment are gradually developing towards full screens. However, increasing screen ratio reduces space where mainstream capacitive fingerprint modules can be placed. Therefore, under-screen optical fingerprint was developed.

As overall technological design capability of electronic products has been improved and consumer's aesthetics have been continuously guided and elevated, an overall trend of mobile phone screens has gradually transformed from a previous diversified design into a full-screen display design. Design capabilities and process capabilities of full-screen related indicators in displays, such as flip-chip films and ultra-narrow frames, have been continuously improved in less than a year, and screen ratio has gradually increased from 80% to 97%. Among this, research on under-screen fingerprint identification is particularly popular. It directly integrates a fingerprint module under the screen to greatly increase screen ratio.

At present, for organic light emitting diode (OLED) display screens, application of under-screen optical fingerprint identification has been increasing. An under-screen optical fingerprint scheme of an OLED display panel refers to detecting fingerprints by illuminating a finger by utilizing light transmittance of the OLED display panel and light of the panel.

### TECHNICAL PROBLEMS

Backlight modules have poor light transmission performance. Although there are many solutions for under-screen fingerprint identification, including pinholes, collimation, etc., due to the backlight, it is difficult to apply a scheme that includes pinhole in an LCD. The main reason is that light reflected by user's finger is transmitted to an image sensor device through the pinhole and an opening area corresponding to pixels at a same time, and in general, an area of the opening area corresponding to the pixels is much larger than an area of the pinhole, so a pinhole imaging signal is easily covered, which in turn makes it difficult for the image sensor device to make an image.

### TECHNICAL SOLUTIONS

In order to solve the above-mentioned problems, an embodiment of the present disclosure provides an under-screen fingerprint identification device, which can effectively solve the problem that an image sensor is difficult to image caused by light passing through a pixel opening area to cover a pinhole imaging signal.

Embodiments of the present disclosure provides an under-screen fingerprint identification device suitable for a display panel. The under-screen fingerprint identification device includes: a light source disposed on a side of the display panel; a plurality of image sensors disposed in a color filter layer of the display panel; and a pinhole layer disposed above the color filter layer of the display panel; wherein the pinhole layer comprises a plurality of light control films and a plurality of pinhole regions, the light control films and the pinhole regions are arranged in intervals, each of the light control films is located at a position corresponding to each pixel of the color filter layer, each of the pinhole regions comprises a pinhole, and each of the pinholes is located at a position corresponding to each of the image sensors.

Furthermore, the light source is a mini-LED or a micro-LED.

Furthermore, light generated by the light source is invisible light.

Furthermore, the invisible light is infrared light.

Furthermore, wirings of the light source are reused touch signal routings of the display panel.

Furthermore, the light control films are configured to transmit visible light.

Furthermore, an aperture of the pinholes is 5um to 50um.

Embodiments of the present disclosure also provides a display panel. The display panel includes any of the above-mentioned under-screen fingerprint identification devices.

Embodiments of the present disclosure also provides a display device. The display device includes the above display panel.

### BENEFICIAL EFFECT

Beneficial effects of the present disclosure are: in the present disclosure, light control films are added to the pixel opening areas to distinguish fingerprint identification light from normal display light, and the image sensors are set to only identify invisible light, so invisible light can be transmitted to the image sensor only through the pinholes in the pinhole layer, thereby improving a signal-to-noise ratio of a fingerprint identification signal.

### DESCRIPTION OF DRAWINGS

In order to more clearly illustrate the technical solutions in the embodiments or the prior art, the drawings to be used in the descriptions of the embodiments or the prior art will be briefly described below. Obviously, the drawings in the following description are merely embodiments of the present disclosure. For those of ordinary skill in the art, other drawings may be obtained from the drawings without any creative work.

FIG. 1 is a schematic view of an under-screen fingerprint identification device in an embodiment of the present disclosure.

FIG. 2 is a schematic plan view of an under-screen fingerprint identification device in an embodiment of the present disclosure.

FIG. 3 is a schematic view of a display panel in an embodiment of the present disclosure.

FIG. 4 is a schematic view of a display device in an embodiment of the present disclosure.

### DETAILED DESCRIPTION OF EMBODIMENTS

Technical solutions in the embodiments of the present disclosure will be clearly and completely described with reference to the accompanying drawings in the embodiments of the present disclosure. Obviously, the described embodiments are only a part of the embodiments of the present disclosure, but not all the embodiments. Based on the embodiments of the present disclosure, all other embodiments obtained by those skilled in the art without creative work fall into a protection scope of the present disclosure.

In the description of the present disclosure, it should be understood that orientational or positional relationships indicated by terms, such as “center”, “longitudinal”, “transverse”, “length”, “width”, “thickness”, “upper”, “lower”, “front ”,“rear”, “left”, “right”, “vertical”, “horizontal”, “top”, “bottom”, “inside”, “outside”, “clockwise”, “counterclockwise”, etc., are based on the orientational or positional relationships shown in the drawings, and are merely for the convenience of describing the present disclosure and simplifying the description, and does not indicate or imply that the device or element referred to must have a specific orientation, be constructed and operate in a specific orientation, and therefore cannot be understood as a limitation on the present disclosure.

In addition, the terms “first” and “second” are used herein for purposes of description, and should not be interpreted as indication or implication of relative importance or implicitly indicating a number of technical features indicated. Thus, the features defined as “first” and “second” may explicitly or implicitly include one or more of the features. In the description of the present disclosure, the meaning of “plurality” is two or more, unless specifically defined otherwise.

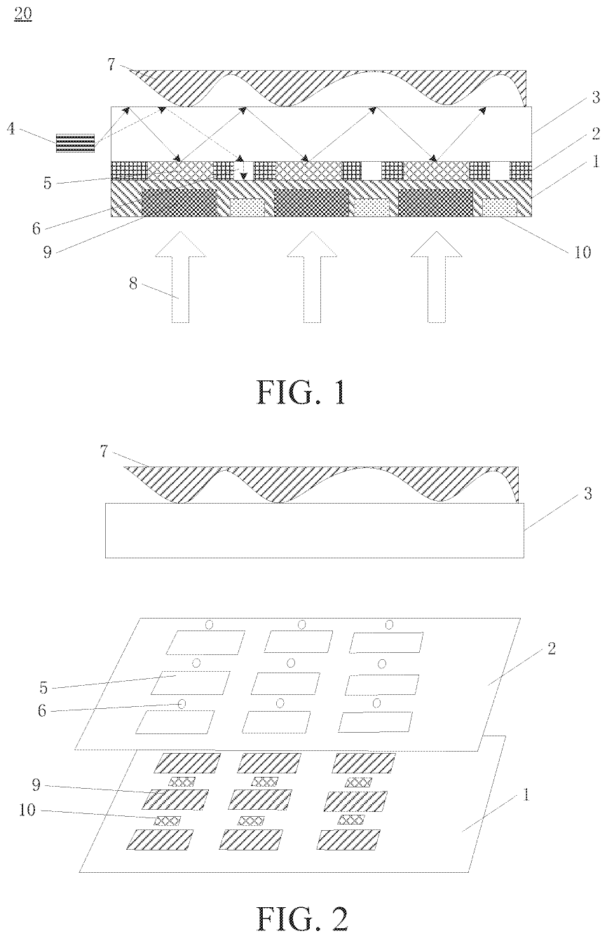

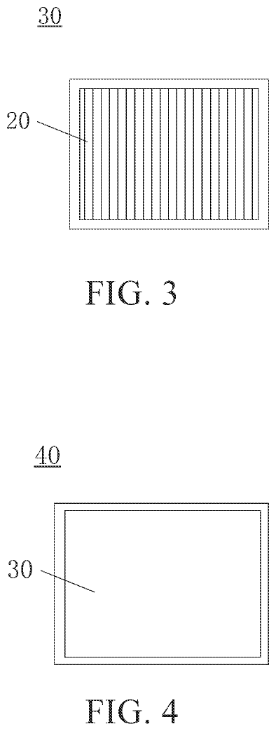

As shown in FIG. 1, it is a schematic view of an under-screen fingerprint identification device in an embodiment of the present disclosure. The under-screen fingerprint identification device is suitable for a display panel. The under-screen fingerprint identification device includes a light source 4, a plurality of image sensors 10, and a pinhole layer 2. Wherein, the display panel shown in FIG. 3 includes a color filter layer 1 and a light guide layer 3.

With reference to FIG. 2, the light source 4 is disposed on a side of the display panel. The plurality of image sensors 10 are disposed in the color filter layer 1 of the display panel 30. The pinhole layer 2 is disposed above the color filter layer 1. The pinhole layer 2 includes a plurality of light control films 5 and a plurality of pinhole regions 12. The light control film 5 and the pinhole region 12 are arranged in intervals. Each of the light control films 5 is located at a position corresponding to each pixel 9 of the color filter layer 1. Each of the pinhole regions 12 includes a pinhole 6, and each pinhole is located at a position corresponding to each of the image sensors 10.

The color filter layer 1 includes pixels 9 and the plurality of image sensors 10 therein.

In an embodiment of the present disclosure, an arrangement of the pixels 9 is in a diamond shaped arrangement. Each pixel unit may include two red subpixels, two blue subpixels, and two green subpixels. However, it is not limited to this. In other embodiments, the pixels 9 may also be arranged in other ways. For example, the three primary colors of RGB are arranged in a manner of 1:1:1.

Wherein, the image sensors 10 use a photoelectric conversion function of a photoelectric device to convert a light image on a photosensitive surface into an electrical signal in a proportional relationship with the light image. Compared with photosensitive elements such as photodiodes, phototransistors, and other “point” light sources, the image sensor is a functional device that divides the light image on its light receiving surface into a plurality of small units and converts the light image into a usable electrical signal. In the embodiments of the present disclosure, each of the image sensors 10 can only identify invisible light sources.

Light emitted from the light source 4 is invisible light, and the invisible light passing through the pinholes 6 can be identified by the image sensors 10 to complete a function of fingerprint identification. The invisible light in the embodiment of the present disclosure is infrared light, but not limited. Invisible light refers to light that cannot be seen by human eyes, and mainly includes ultraviolet light and far-infrared light. A wavelength of electromagnetic waves that human eyes can perceive is between 400 and 700 nanometers.

The light source is a mini organic light emitting diode (mini-LED) or a micro organic light emitting diode (micro-LED). Wherein, a dimension of the mini-LED is about 100 microns, and an advantage of the mini-LED is that it is easier to mass-produce. Whereas, a dimension of the micro-LED is about 1 to 100 microns, and advantages of the micro-LED are high efficiency, high brightness, high reliability, and short response times.

Wirings of the light source 4 are reused touch signal routings of a display panel, and the touch signal routings are twisted pairs. Since the twisted-pair signal lines do not start working properly during fingerprint identification, the twisted-pair signal lines can be used as wirings of the light source. However, it is not limited to this. On the premise that a normal operation of the display panel is not affected, other wirings can be reused in other embodiments, thereby saving space and cost.

The pinhole layer 2 includes a plurality of the pinholes 6 and a plurality of light control films 5. An aperture of the pinholes 6 is about 5 μm to 50 μm. In this embodiment of the present disclosure, the aperture of the pinholes 6 is 10 μm.

Wherein, the pinholes 6 are configured to transmit invisible light generated by the light source 4. The light control films 5 are configured to transmit normal visible light 8 generated by the color filter layer 1, to reflect the invisible light generated by the light source 4. This way, invisible light can be transmitted to the image sensors 10 only through the pinholes 6, thereby improving the signal-to-noise ratio of the fingerprint identification signal.

Beneficial effects of the present disclosure are: in the present disclosure, light control films are added to the pixel opening areas to distinguish fingerprint identification light from normal display light, and the image sensors are set to only identify invisible light, so invisible light can be transmitted to the image sensors only through the pinholes in the pinhole layer, thereby improving the signal-to-noise ratio of the fingerprint identification signal.

As shown in FIG. 3, it is a schematic view of a display panel 30 in an embodiment of the present disclosure. The display panel 30 includes the under-screen fingerprint identification device 20 described in the above embodiments.

As shown in FIG. 4, it is a schematic view of a display device 40 in an embodiment of the present disclosure. The display device 40 includes the display panel 30 described in the above embodiments. The display device 30 may be any product or component having a display function, such as a mobile phone, a tablet computer, a television, a display, a notebook computer, a digital photo frame, a navigator, and the like.

In summary, although the present disclosure is disclosed as above with the preferred embodiments, the above-mentioned preferred embodiments are not intended to limit the present disclosure. Those skilled in the art can make various modifications and improvements without departing from the spirit and scope of the present disclosure. Therefore, a protection scope of the disclosure is based on a scope defined by the claims.

### INDUSTRIAL APPLICABILITY

The subject matter of the present disclosure can be manufactured and used in industry with industrial applicability.

What is claimed is:

1. An under-screen fingerprint identification device, suitable for a display panel, comprising:
a light source disposed on a side of the display panel;
a plurality of image sensors disposed in a color filter layer of the display panel; and
a pinhole layer disposed above the color filter layer of the display panel;
wherein the pinhole layer comprises a plurality of light control films and a plurality of pinhole regions, the light control films and the pinhole regions are arranged in intervals, each of the light control films is located at a position corresponding to each pixel of the color filter layer, each of the pinhole regions comprises a pinhole, and each of the pinholes is located at a position corresponding to each of the image sensors.

2. The under-screen fingerprint identification device as claimed in claim 1, wherein the light source is a mini-LED or a micro-LED.

3. The under-screen fingerprint identification device as claimed in claim 1, wherein light generated by the light source is invisible light.

4. The under-screen fingerprint identification device as claimed in claim 3, wherein the invisible light is infrared light.

5. The under-screen fingerprint identification device as claimed in claim 1, wherein wirings of the light source are reused touch signal routings of the display panel.

6. The under-screen fingerprint identification device as claimed in claim 1, wherein the light control films are configured to transmit visible light.

7. The under-screen fingerprint identification device as claimed in claim 1, wherein each of the image sensors are set to only identify invisible light.

8. The under-screen fingerprint identification device as claimed in claim 1, wherein an aperture of the pinholes is 5 82 m to 50 μm.

9. A display panel, comprising the under-screen fingerprint identification device as claimed in claim 1.

10. A display device, comprising the display panel as claimed in claim 9.
